(19) United States
(12) Patent Application Publication
(10) Pub. No.: US 2013/0112240 A1
(43) Pub. Date: May 9, 2013

(54) POLAR-AXIS SOLAR TRACKER

(71) Applicants: Stavros Mastorakis, Fustinana (ES); Jose Carlos Alpuente Luengo, Fustinana (ES); Nuria Diaz Contador, Fustinana (ES); Diego Leon Muñoz, Fustinana (ES); Ana Isabel Casbas Alejandre, Fustinana (ES)

(72) Inventors: Stavros Mastorakis, Fustinana (ES); Jose Carlos Alpuente Luengo, Fustinana (ES); Nuria Diaz Contador, Fustinana (ES); Diego Leon Muñoz, Fustinana (ES); Ana Isabel Casbas Alejandre, Fustinana (ES)

(73) Assignee: MECANIZADOS SOLARES, S.L., Fustinana (ES)

(21) Appl. No.: 13/451,874

(22) Filed: Apr. 20, 2012

(30) Foreign Application Priority Data
Nov. 3, 2011 (ES) P201101191

(51) Int. Cl. H01L 31/052

(52) U.S. Cl. 136/246

(57) ABSTRACT

The present invention relates to a polar-axis solar tracker comprising a series of rows of photovoltaic modules arranged on support structures formed by stringers and longitudinal shafts, wherein the support structures of the rows of photovoltaic modules are articulated in rotating assembly by means of hinges which establish an axis of rotation parallel to the shaft of said support structures of the photovoltaic modules, having an operating system which actuates the longitudinal movement of a bar, which actuates the pivoting rotation of the support structures of the photovoltaic modules on the corresponding hinges and through the connecting rods.

### SECTOR OF THE ART

The present invention relates to a single-axis solar tracker having multiple photovoltaic modules tilted towards the sun which are rotated during the day for the purpose of being able to capture sunlight during the maximum time and in the most effective manner possible.

### STATE OF THE ART

Single-axis solar trackers, which have the objective of rotating photovoltaic modules which make up the solar tracker, for orienting said photovoltaic modules towards the sun and thus being able to capture the greatest amount of solar energy possible, are already known today.

The main problem of solar trackers of this type existing today is that photovoltaic modules rotate directly about the longitudinal shaft of a supporting structure thereof.

This aspect means that over time, allowances will appear in the system resulting in a less precise rotation of the photovoltaic modules and consequently a less effective capture of solar energy; it further causes the solar tracker to be more prone to break-downs and to need a higher maintenance cost to maintain it in an optimum operating state.

### OBJECT OF THE INVENTION

According to the present invention a single axis solar tracker having multiple photovoltaic modules orientated towards the sun, which are incorporated on a support structure having a rotation system for the purpose of being able to capture sunlight with the photovoltaic modules during the maximum time and in the most effective manner possible is proposed.

The main advantage that this solar tracker offers is in its rotation system, since unlike existing solar trackers of this type, the rotation of photovoltaic modules does not take place directly about the longitudinal shaft of the structure supporting them, but in this case the rotation is performed with respect to the longitudinal shaft on articulations formed by hinges.

Said aforementioned hinges are secured to the shaft of the support structure of the photovoltaic modules and have articulation bolts which are in a position parallel to said shaft of the support structure of the photovoltaic modules, such that the group of photovoltaic modules is rotated about the mentioned bolts of the hinges. The allowances produced in conventional solar trackers with the rotation about the shaft of the support structure of the photovoltaic modules are therefore eliminated.

By eliminating the possible allowances of the solar tracker produced over time, the rotation of the photovoltaic modules of the solar tracker is much more precise and therefore capturing solar energy is more effectively done.

Another aspect to highlight is that with this rotating assembly arrangement of the photovoltaic modules, the stress which the shaft of the support structure of the photovoltaic modules has to withstand is reduced, whereby fewer break-downs occur, and the required maintenance is therefore less.

### DESCRIPTION OF THE DRAWINGS

FIG. 1 shows a bottom perspective view of a solar tracker according to the invention, the support structure of the photovoltaic modules and the rotation system being seen.

FIG. 2 shows a top plan view of the solar tracker without the photovoltaic modules.

FIG. 3 shows a profile view of the solar tracker without the photovoltaic modules, being able to see the inclined position of the support structure of the photovoltaic modules.

FIG. 4 shows an enlarged view of the rotation operating system for orientating the photovoltaic modules of the solar tracker.

FIG. 5 shows the same detail of the preceding figure from another observation angle.

FIG. 6 shows a perspective view of a single hinge of the rotating assembly of the support structure of the photovoltaic modules in the solar tracker.

FIG. 7 shows an exploded perspective view of the hinge of the preceding figure.

FIG. 8 shows a double hinge of the rotating assembly of the support structure of the photovoltaic modules in the solar tracker.

FIG. 9 shows a detailed view of the assembly of a single hinge of the rotation in the solar tracker.

FIG. 10 shows a detailed view of the assembly of a double hinge of the rotation in the solar tracker.

### DETAILED DESCRIPTION OF THE INVENTION

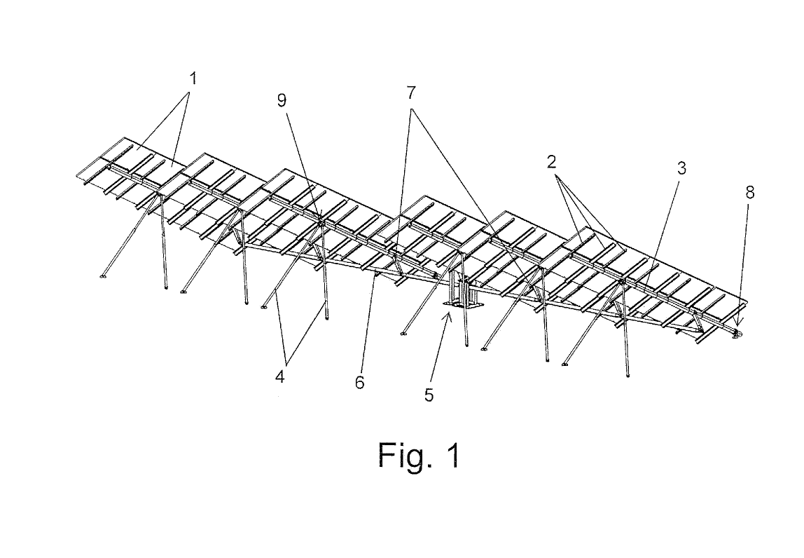

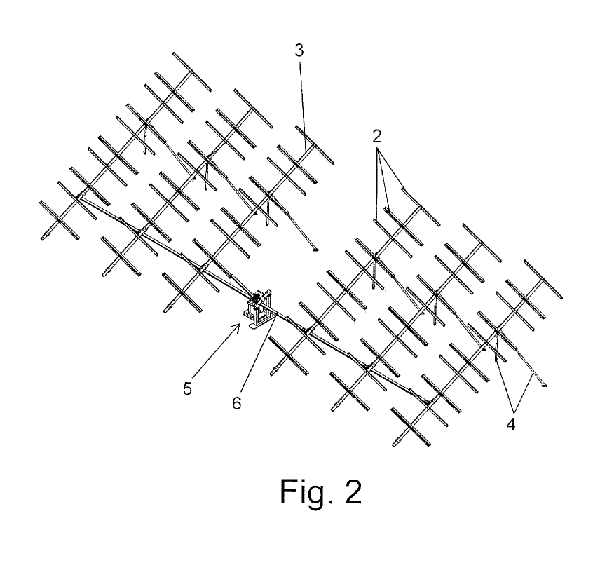

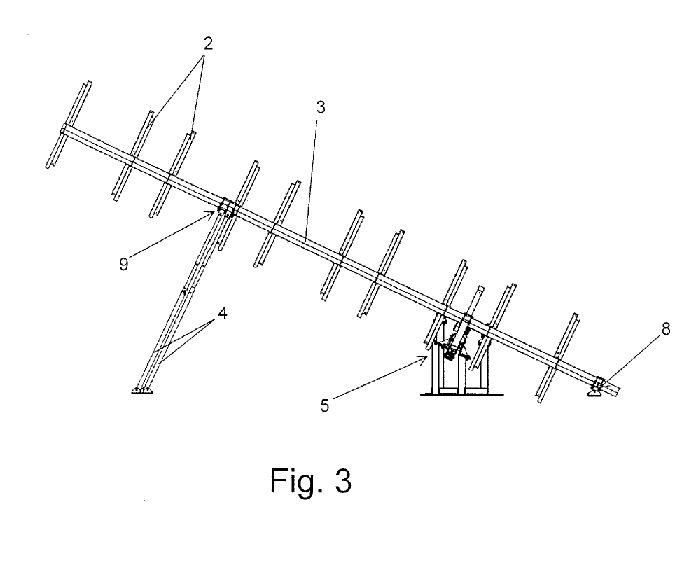

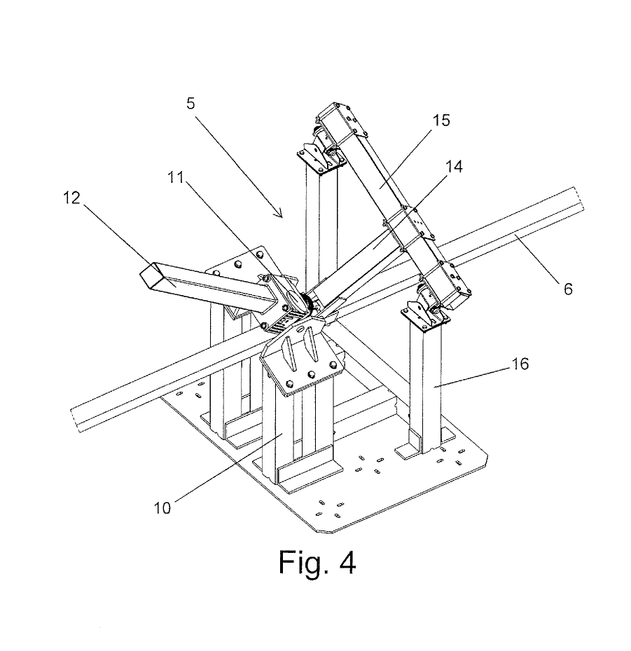

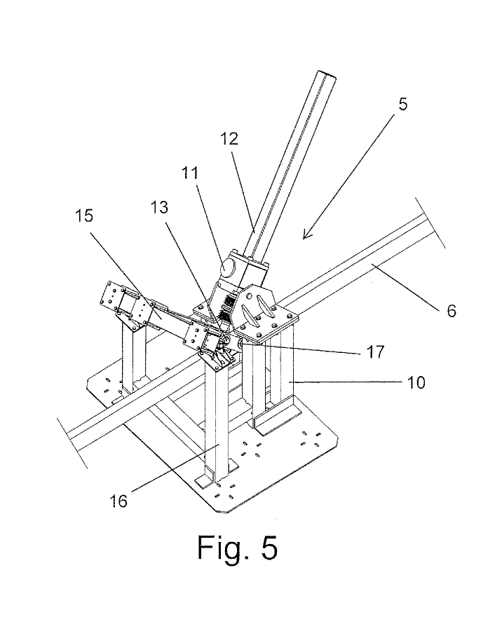

The object of the invention relates to a solar tracker that, as can be seen in FIG. 1, is made up of TOWS of photovoltaic modules (1), the photovoltaic modules (1) of each row being incorporated on a structure formed by stringers (2) and a longitudinal shaft (3), such that the group of each row is arranged in an inclined position with respect to a horizontal plane, as can be seen in FIG. 3.

This inclination is because the support structure of the photovoltaic modules (1) is anchored at one end directly on a foundation element, while in an area close to the other end it is supported with legs (4) keeping structure elevated.

The solar tracker has a rotation operating system (5), whereby a bar (6) which is attached by means of connecting rods (7) to the longitudinal shafts (3) of all the support structures of the rows of photovoltaic modules (1), which rotate on hinges (8 and 9), is moved.

The rotation operating system (5) comprises a support formed by a pillar structure (10) on which a motor (11) is arranged which actuates the linear movement of a slide bar (12), which is attached by means of an articulation (13) with a pivoting arm (14) which is integral with a bar-shaft (15) arranged in a rotating assembly on another pillar structure (16), said pivoting arm (14) in turn being attached by means of an articulation (17) to the bar (6) which is attached to the support structures of the rows of photovoltaic modules (1).

The operation of the motor (11) therefore moves the slide bar (12), which makes the pivoting arm (14) pivot when moved, said pivoting arm moving the bar (6) in a longitudinal movement, such that this movement is transferred to the support structures of the rows of photovoltaic modules (1) through the connecting rods(7), whereby producing a rotating movement of said support structures of the rows of photovoltaic modules (1) on the corresponding hinges (8 and 9).

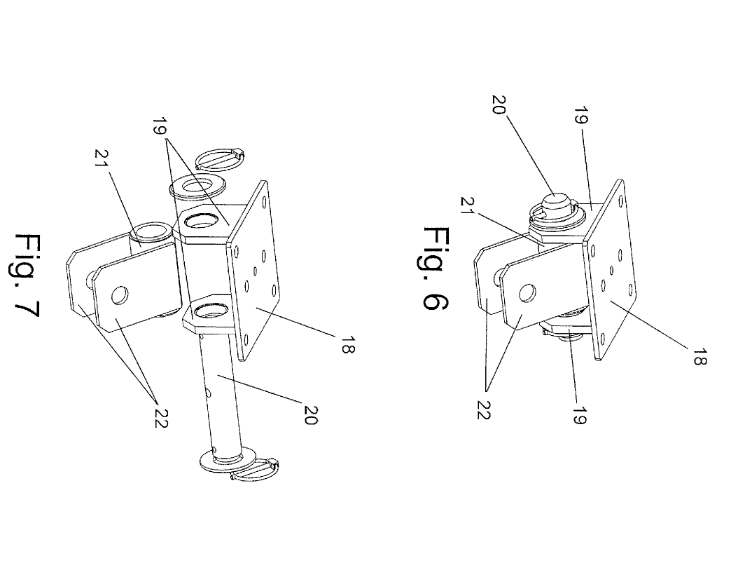

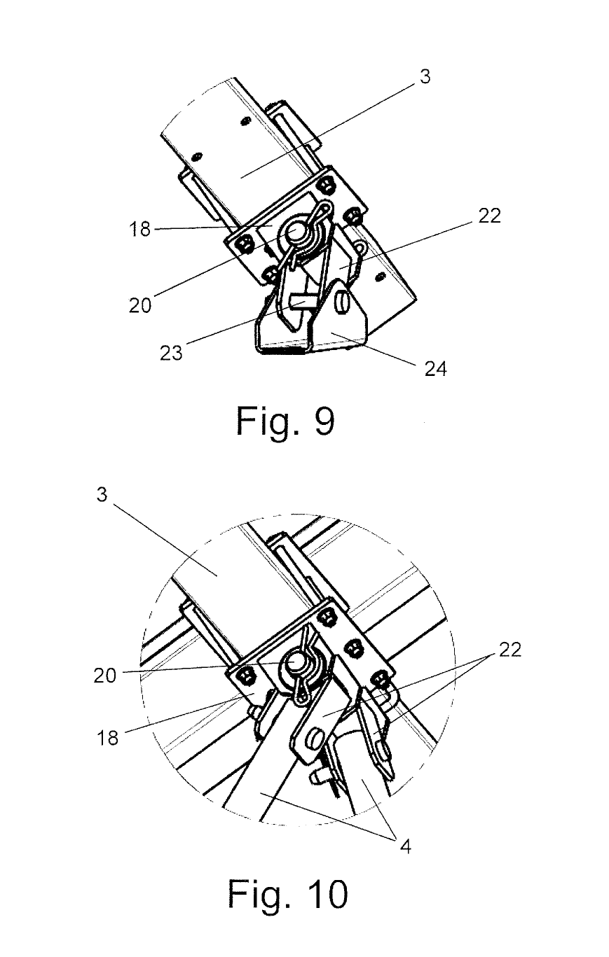

FIGS. 6 and 7 show the structural formation of an anchoring hinge (8) for anchoring the support structures of the photovoltaic modules directly on a foundation element, comprising a base plate (18) intended for being fixed to the axis (3) of the corresponding support structure of photovoltaic modules (1), from which base plate (18) there project lugs (19) which are traversed by a bolt (20), on which there is incorporated a bushing (21) from which there in turn project lugs (22) which, as seen in FIG. 9, are intended for establishing an articulated relation, by means of another bolt (23), with an anchoring base (24) intended for being fixed on the ground.

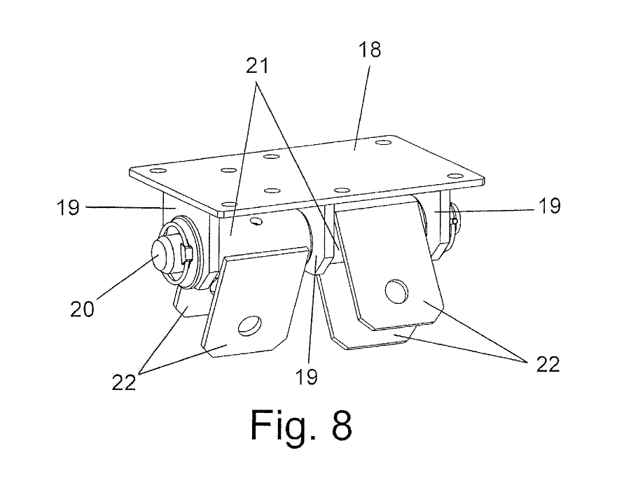

FIG. 8 shows a hinge (9) for attaching the support structures of the photovoltaic modules (1) on the supporting legs (4), the structural formation of this hinge (9) being the same as that of the hinge (8) described above but with three lugs (19) projecting from the base plate (18) and between them, on the same articulation bolt (20), two independent bushings (21) provided with lugs (22) for being fixed on the supporting legs (4), as seen in FIG. 10.

1. A polar axis solar tracker comprising a series of rows of photovoltaic modules arranged on support structures formed by stringers and longitudinal shafts, wherein the support structures of the rows of photovoltaic modules are articulated in a pivoting rotation assembly by means of hinges which establish a axis of rotation parallel to the shaft of said support structures of the photovoltaic modules, having an operating system which actuates the longitudinal movement of a bar, which actuates the pivoting rotation of the support structures of the photovoltaic modules on the corresponding hinges through connecting rods.

2. The polar-axis solar tracker according to claim 1, wherein the hinges comprise a base plate intended for being fixed to the shaft of the support structures of the photovoltaic modules, from which base plate there project lugs which are traversed by a bolt from which there in turn project lugs intended for securing the corresponding hinge on the other side.

3. The polar-axis solar tracker according to claim 1, wherein the hinges have only one bushing by means of the lugs of which an articulated relation is established by means of a bolt with an anchoring base intended for being fixed on the ground.

4. The polar-axis solar tracker according to claim 1, wherein the hinges have two independent bushings which are fixed by means of lugs on the supporting legs.

5. The polar-axis solar tracker according to claim 1, wherein the operating system comprising a support formed by a pillar structure on which a motor is arranged which actuates the linear movement of a slide bar, which is attached by means of an articulation to a pivoting arm integral with a bar-shaft arranged on another pillar structure, the pivoting arm in turn being attached, by means of an articulation, to the bar which actuates the pivoting rotation of the support structures of the photovoltaic modules.

6. The polar-axis solar tracker according to claim 2, wherein the hinges have only one bushing by means of the lugs of which an articulated relation is established by means of a bolt with an anchoring base intended for being fixed on the ground.

7. The polar-axis solar tracker according to claim 2, wherein the hinges have two independent bushings which are fixed by means of lugs on the supporting legs.
